(19) United States
(12) Patent Application Publication
(10) Pub. No.: US 2025/0248145 A1
(43) Pub. Date: Jul. 31, 2025

(54) IMAGE SENSOR

(71) Applicant: Taiwan Semiconductor Manufacturing Company, Ltd., Hsinchu (TW)

(72) Inventors: Keng-Yu Chou, Kaohsiung City (TW); Cheng-Yu Huang, Hsinchu (TW); Yi-Hsuan Wang, Hsinchu City (TW); Cheng-Ying Ho, Chiayi County (TW); Kai-Chun Hsu, New Taiepi City (TW); Tzu-Jui Wang, Kaohsiung City (TW); Bo-Yuan Su, Hsinchu County (TW); Wei-Chieh Chiang, Changhua County (TW); Feng-Chi Hung, Hsin-Chu County (TW)

(73) Assignee: Taiwan Semiconductor Manufacturing Company, Ltd., Hsinchu (TW)

(21) Appl. No.: 18/427,823

(22) Filed: Jan. 31, 2024

(51) Int. Cl. H01L 27/146; H04N 25/704

(52) U.S. Cl. CPC H10F 39/802; H04N 25/704; H10F 39/182; H10F 39/807

(57) ABSTRACT

An image sensor includes a plurality of pixels. At least one pixel includes first and second photosensitive regions, first and second transfer gate transistors and a floating diffusion region. The first and second photosensitive regions are located within a substrate and adjacent to each other. The first and second photosensitive regions are different in at least one of doping depth and conductivity type. The first and second photosensitive regions are overlapped with an opening of a grid structure disposed on a backside surface of the substrate. The first and second transfer gate transistors are disposed on a frontside surface of the substrate and respectively overlapped with the first and second photosensitive regions. The floating diffusion region is located within the substrate and shared between the first and second photosensitive regions.

### BACKGROUND

Integrated circuits (IC) with image sensors are used in a wide range of modern day electronic devices. In recent years, complementary metal-oxide semiconductor (CMOS) image sensors (CISs) have begun to see widespread use, largely replacing charge-coupled devices (CCD) image sensors. Compared to CCD image sensors, CISs are increasingly favored due to low power consumption, a small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 and FIG. 2 are respectively a schematic top view and a schematic sectional view of an image sensor according to some embodiments of the present disclosure.

FIG. 3 is another schematic sectional view of an image sensor according to some embodiments of the present disclosure.

FIG. 4 and FIG. 5 are two kinds of equivalent circuit diagrams of a pixel in FIGS. 1 to 3.

FIG. 6 and FIG. 7 are respectively a schematic top view and a schematic sectional view of an image sensor according to some embodiments of the present disclosure.

FIG. 8 is an equivalent circuit diagram of a pixel in FIG. 6 and FIG. 7.

FIG. 9 and FIG. 10 are respectively a schematic top view and a schematic sectional view of an image sensor according to some embodiments of the present disclosure.

FIG. 11 is an equivalent circuit diagram of a pixel in FIG. 9 and FIG. 10.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many electronic devices (e.g., cameras, cellular telephones, computers, etc.) include an image sensor (e.g., an image sensor integrated chip (IC)) for capturing images. One example of such an image sensor is a complementary metal-oxide semiconductor image sensor (CIS) with phase detection autofocus (PDAF).

Some CIS with PDAF include image sensing pixels that are configured to detect (e.g., capture) an image and at least a pair of PDAF pixels that are configured to determine a focus condition (e.g., correctly focused, focused too near, focused too far, etc.) of a specific point or area of the image. The focus condition is determined based on whether a phase difference exists between electrical signal(s) generated by PDAF photodetectors (or photodiodes) of the pair of PDAF pixels. The CIS with PDAF is configured to output a focusing signal (e.g., an electrical signal) based on the focus condition, such that the electronic device can autofocus on the specific point or area of the image (e.g., the CIS with PDAF generates the focusing signal and provides the focusing signal to an actuator (e.g., electronic motor) of the electronic device, thereby causing the actuator to move an optical lens (e.g., main lens) of the electronic device to automatically focus on the specific point or area of the image).

For PDAF pixels with multiple photodiodes (e.g., dual photodiodes or quad photodiodes) designed with lateral overflow integrated capacitance (LOFIC), a grid structure (e.g., metal grid) is required to shield half of the photodiodes in each PDAF pixel for binning output. For example, photodiode(s) in the left half of one PDAF pixel among the pair of PDAF pixels and photodiode(s) in the right half of the other one PDAF pixel among the pair of PDAF pixels shall be shielded by a metal grid for PDAF. However, the large-area grid structure causes light reflection, leading to crosstalk with adjacent pixels (e.g., adjacent image sensing pixels), resulting in poor image sensing quality.

In the present disclosure, the photodiodes (or photosensitive regions) that shall be shielded by the grid structure in the conventional technology are disabled by implant removal, doping depth reduction, conductivity type change or pixel device design. Therefore, portions of the grid structure that are used to shield the photodiodes in the PDAF pixels can be removed. As such, the area of the grid structure can be reduced, and hence the crosstalk issue can be improved.

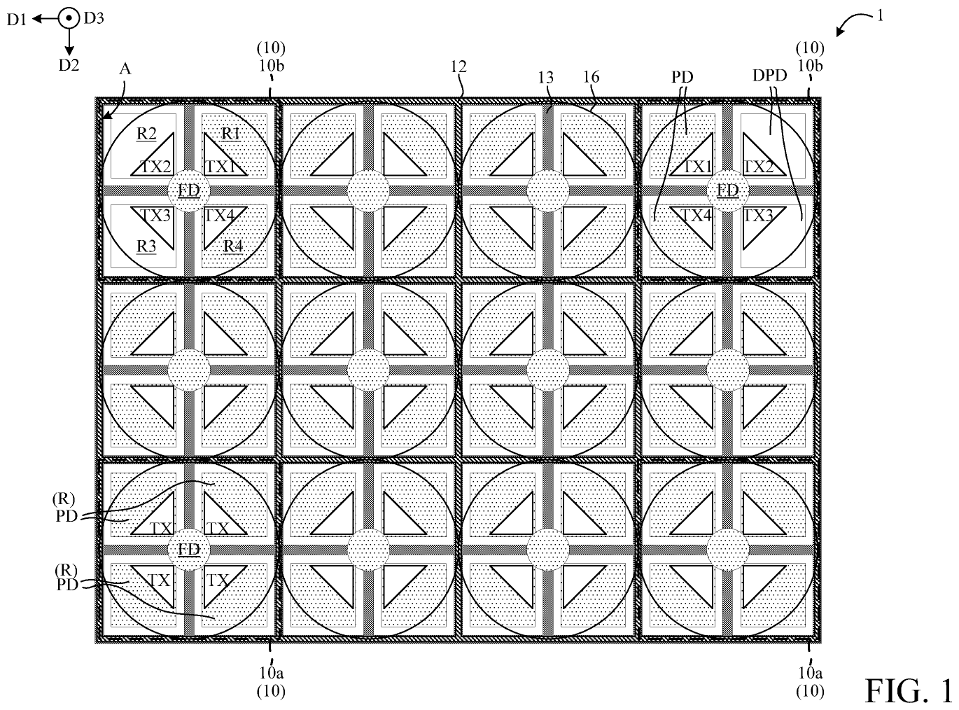

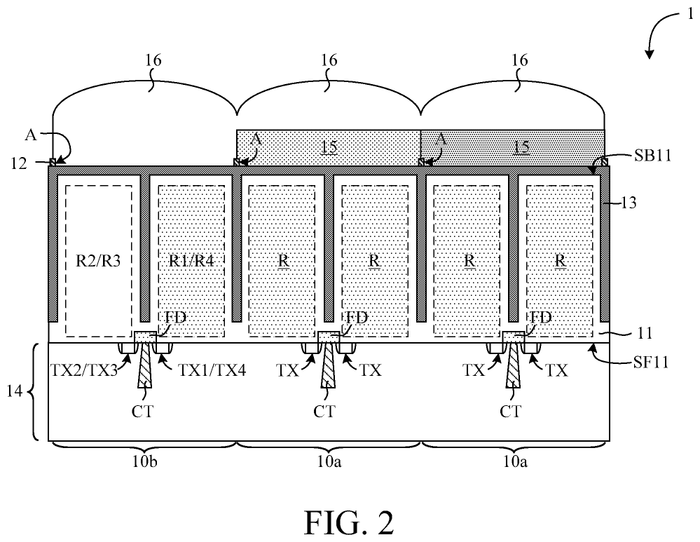

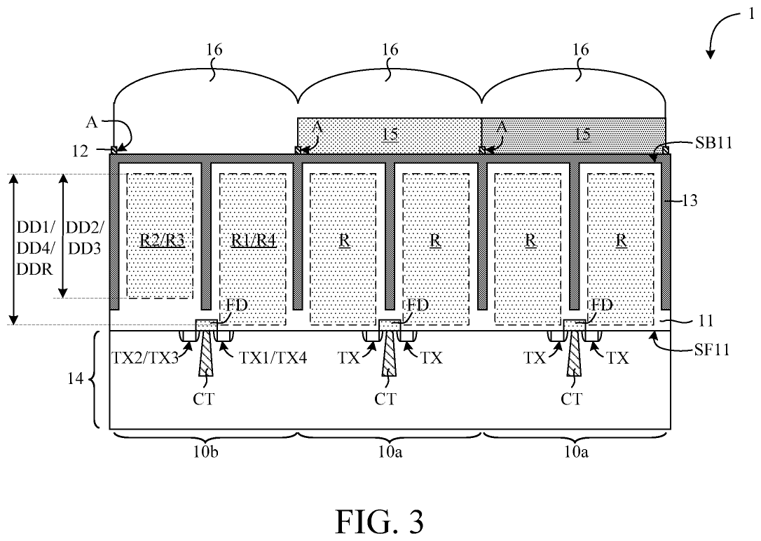

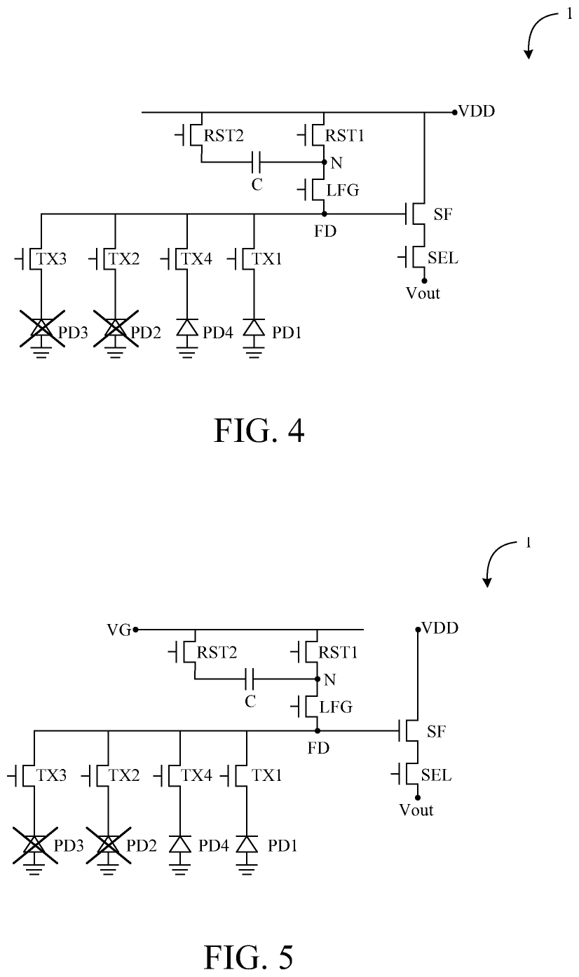

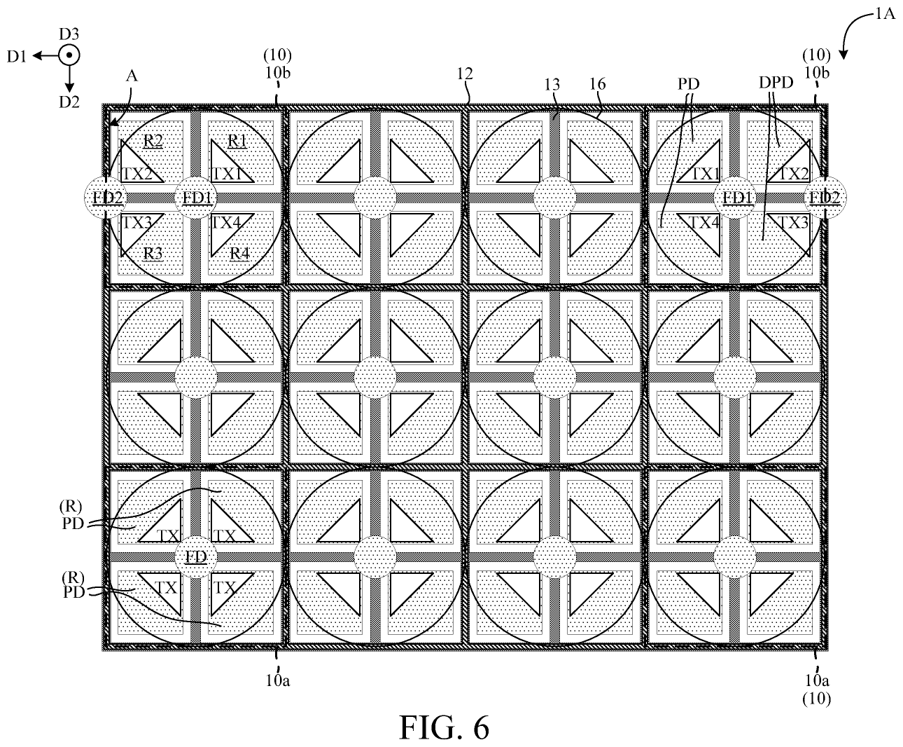

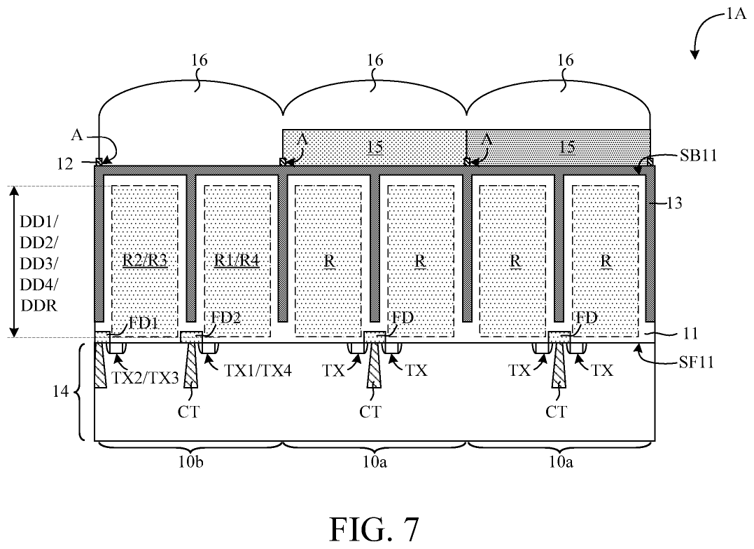

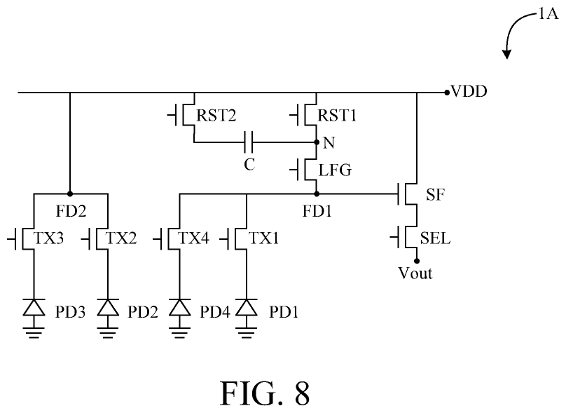

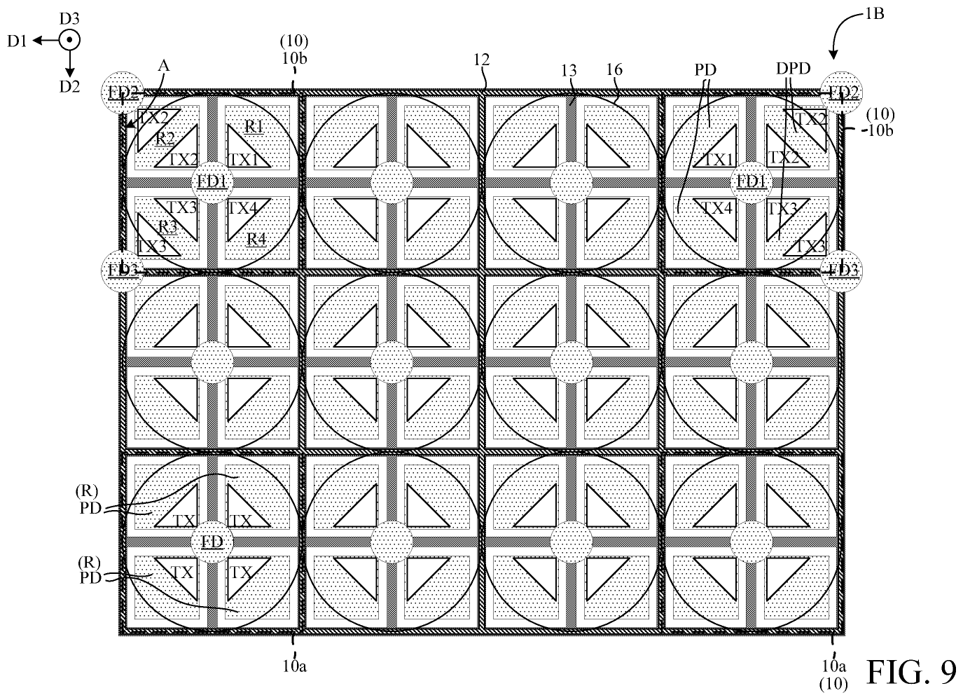

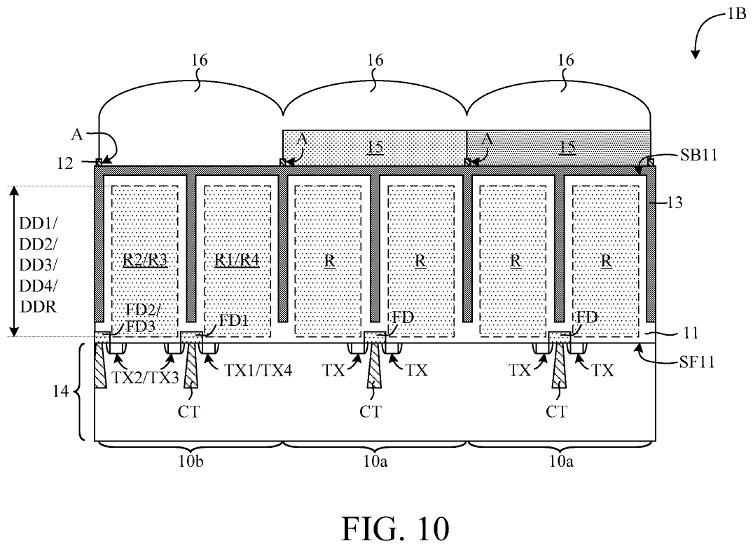

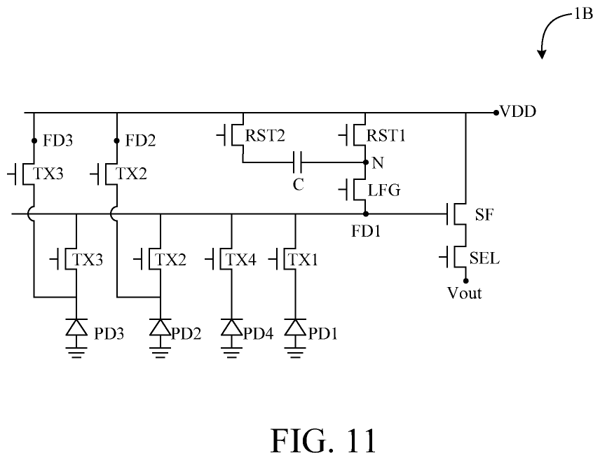

FIG. 1 and FIG. 2 are respectively a schematic top view and a schematic sectional view of an image sensor according to some embodiments of the present disclosure. FIG. 3 is another schematic sectional view of an image sensor according to some embodiments of the present disclosure. FIG. 4 and FIG. 5 are two kinds of equivalent circuit diagrams of a pixel in FIGS. 1 to 3. FIG. 6 and FIG. 7 are respectively a schematic top view and a schematic sectional view of an image sensor according to some embodiments of the present disclosure. FIG. 8 is an equivalent circuit diagram of a pixel in FIG. 6 and FIG. 7. FIG. 9 and FIG. 10 are respectively a schematic top view and a schematic sectional view of an image sensor according to some embodiments of the present disclosure. FIG. 11 is an equivalent circuit diagram of a pixel in FIG. 9 and FIG. 10.

Referring to FIG. 1 and FIG. 2, an image sensor 1 according to some embodiments of the present disclosure is provided. The image sensor 1 includes a plurality of pixels 10. For the simplicity of the drawing, twelve pixels 10 are schematically shown in FIG. 1, but the number of the plurality of pixels 10 are not limited thereto.

In some embodiments, the plurality of pixels 10 are arranged along a first direction D1 and a second direction D2 into an array. The second direction D2 and the first direction D1 intersect each other (e.g., perpendicular to each other) and both perpendicular to a thickness direction (e.g., a third direction D3) of the image sensor 1.

In some embodiments, the plurality of pixels 10 include a plurality of image sensing pixels 10a and a plurality of PDAF pixels 10b inserted between the plurality of image sensing pixels 10a. In some embodiments, the number of the plurality of PDAF pixels 10b is less than the number of the plurality of image sensing pixels 10a. In some embodiments, the number of the plurality of PDAF pixels 10b is 2% to 3% of the number of the plurality of pixels 10, but not limited thereto.

In some embodiments, each of the plurality of image sensing pixels 10a includes a plurality of photodiodes PD (e.g., dual photodiodes or quad photodiodes, but not limited thereto). In some embodiments, each of the plurality of PDAF pixels 10b includes one or more photodiode(s) PD and one or more disabled photodiode(s) DPD. The disabled photodiode DPD refers to the photodiode that is disabled by means of implant removal, doping depth reduction, conductivity type change or pixel device design, such that the electrons generated in the photodiode through light irradiation cannot be transferred to a specified device (e.g., a lateral overflow integration capacitor) that stores the electrons. In some embodiments, the total number of the photodiode(s) PD and the disabled photodiode(s) DPD in each of the plurality of PDAF pixels 10b may be the same as the number of the photodiode(s) PD in each of the plurality of image sensing pixels 10a.

In some embodiments, the arrangement relationship between photodiode(s) PD and disabled photodiode(s) DPD in two adjacent PDAF pixels 10b is opposite to enable PDAF. For example, in the PDAF pixel 10b on the left in FIG. 1, the disabled photodiodes DPD are located on the left half of the PDAF pixel 10b, while the photodiodes PD are located on the right half of the PDAF pixel 10b. On the other hand, in the PDAF pixel 10b on the right in FIG. 1, the disabled photodiodes DPD are located on the right half of the PDAF pixel 10b, while the photodiodes PD are located on the left half of the PDAF pixel 10b.

In the image sensor 1, at least one pixel (e.g., the PDAF pixel 10b) among the plurality of pixels 10 includes a first photosensitive region R1, a second photosensitive region R2, a first transfer gate transistor TX1, a second transfer gate transistor TX2 and a floating diffusion region FD. The first photosensitive region R1 is located within a substrate 11. The second photosensitive region R2 is located within the substrate 11 and next to the first photosensitive region R1. The first photosensitive region R1 and the second photosensitive region R2 are different in at least one of doping depth and conductivity type, and the first photosensitive region R1 and the second photosensitive region R2 are overlapped with an opening A of a grid structure 12 disposed on a backside surface SB11 of the substrate 11. The first transfer gate transistor TX1 is disposed on a frontside surface SF11 of the substrate 11 and overlapped with the first photosensitive region R1. The second transfer gate transistor TX2 is disposed on the frontside surface SF11 of the substrate 11 and overlapped with the second photosensitive region R2. The floating diffusion region FD is located within the substrate 11 and shared between the first photosensitive region R1 and the second photosensitive region R2.

Specifically, the substrate 11 may, for example, be or include a semiconductor material such as silicon, crystalline silicon, monocrystalline silicon, bulk silicon, epitaxial silicon, another semiconductor material, the like, or any combination of the foregoing.

The first photosensitive region R1 and the second photosensitive region R2 within the substrate 11 are spaced apart from each other. For example, the image sensor 1 may further include an isolation structure 13 to separate and electrically isolate the first photosensitive region R1 from the second photosensitive region R2. The isolation structure 13 is disposed from the backside surface SB11 to a point between the backside surface SB11 and the frontside surface SF11, and the isolation structure 13 is disposed laterally between the first photosensitive region R1 and the second photosensitive region R2. In some embodiments, the isolation structure 12 may, for example, be configured as a back-side trench isolation (BTI) structure, a back-side deep trench isolation (BDTI) structure, another suitable isolation structure, or the like.

In some embodiments, the first photosensitive region R1 may be referred to as a first photodetector or a first photodiode PD1 (see FIG. 4 or FIG. 5), and the second photosensitive region R2 may be referred to as a second photodetector or a second photodiode PD2 (see FIG. 4 or FIG. 5). In some embodiments, the first photosensitive region R1 and the second photosensitive region R2 are formed within the substrate 11 through one or more selective ion implantation processes. In some embodiments, the first photosensitive region R1 has a first conductivity type, the second photosensitive region R2 and the substrate 11 have a second conductivity type different from the first conductivity type. In some embodiments, the first conductivity type is n-type, and the second conductivity type is p-type, or vice versa.

In some embodiments, the conductivity type and the impurity concentration of the second photosensitive region R2 may be the same as those of the substrate 11. Take FIG. 2 as an example, both of the substrate 11 and the second photosensitive region R2 may be p-type, and the impurity concentration of both of the substrate 11 and the second photosensitive region R2 may be in a range of from about 10¹⁵/cm³ to about 3*10¹⁵/cm³. In these embodiments, the second photodiode (the second photosensitive region R2) is disabled by not doping the second photosensitive region R2 with the first conductivity type dopant when performing ion implantation on the first photosensitive region R1. Since the second photodiode (the second photosensitive region R2) is disabled, it is not necessary to shield the second photodiode (the second photosensitive region R2) with the grid structure 12 to enable PDAF, and thus portions of the grid structure 12 used to shield the second photodiode (the second photosensitive region R2) can be removed and both of the first photosensitive region R1 and the second photosensitive region R2 can be exposed by the opening A of the grid structure 12. In this way, the area of the grid structure 12 can be reduced, and hence the crosstalk issue can be improved. Since there is no need to use the grid structure 12 to shield the second photosensitive region R2, the grid structure 12 may, for example, include a metal grid structure and/or a dielectric grid structure. A material of the metal grid structure may, for example, include aluminum, copper, tungsten, another material, or any combination of the foregoing. A material of the dielectric grid structure may, for example, include an oxide such as silicon dioxide, another dielectric material, or any combination of the foregoing.

In some alternative embodiments, the conductivity type of the second photosensitive region R2 may be the same as that of the substrate 11, while the impurity concentration of the second photosensitive region R2 may be higher than that of the substrate 11. For example, the second photosensitive region R2 may be doped with higher concentration of P-type dopants through an additional ion implantation process, and the impurity concentration of the second photosensitive region R2 may be about 10²⁰/cm³ or more, but not limited thereto. In these embodiments, electrons generated in the second photosensitive region R2 through light irradiation may be recombined with the high concentration of P-type dopants. In this way, crosstalk caused by electron transfer to an adjacent photosensitive region (e.g., the first photosensitive region R1) can be reduced.

In some other embodiments, as shown in FIG. 3, the second photodiode (the second photosensitive region R2) can be disabled by increasing the distance between the second photosensitive region R2 and the floating diffusion region FD. For example, the conductivity type of the second photosensitive region R2 may be the same as that of the first photosensitive region R1, and the doping depth DD2 of the second photosensitive region R2 may be smaller than the doping depth DD1 of the first photosensitive region R1 so that a distance (e.g., a minimum distance along the third direction D3) between the second photosensitive region R2 and the floating diffusion region FD is larger than a distance between the first photosensitive region R1 and the floating diffusion region FD.

The floating diffusion region FD is disposed adjacent to the frontside surface SF11 of the substrate 11 and located between the first photosensitive region R1 and the second photosensitive region R2. In some embodiments, the conductivity type of the floating diffusion region FD may be the same as that of the first photosensitive region R1. In some embodiments, the floating diffusion region FD may serve as a capacitor for storing the image charges.

The first transfer gate transistor TX1 and the second transfer gate transistor TX2 are disposed adjacent to the floating diffusion region FD. In some embodiments, although not marked/shown, each of the transfer gate transistors (including the first transfer gate transistor TX1 and the second transfer gate transistor TX2) includes a gate structure and a sidewall spacer structure that laterally encloses the gate structure. In further embodiments, although not marked/shown, the gate structure includes a gate electrode overlying the substrate and a gate dielectric layer disposed between the substrate and the gate electrode.

In some embodiments, the first transfer gate transistor TX1 and the second transfer gate transistor TX2 are within an interconnect structure 14 disposed on the frontside surface SF11 of the substrate 11. In some embodiments, the interconnect structure 14 includes an interconnect dielectric structure (not shown), a plurality of conductive wires within the interconnect dielectric structure, a plurality of conductive vias (not shown) within the interconnect dielectric structure and a plurality of contacts CT within the interconnect dielectric structure and connected to the floating diffusion regions FD.

In some embodiments, the at least one pixel (e.g., the PDAF pixel 10b) among the plurality of pixels 10 further includes a third photosensitive region R3, a fourth photosensitive region R4, a third transfer gate transistor TX3 and a fourth transfer gate transistor TX4, but not limited thereto. In some alternative embodiments, the at least one pixel (e.g., the PDAF pixel 10b) among the plurality of pixels 10 does not include the third photosensitive region R3, the fourth photosensitive region R4, the third transfer gate transistor TX3 and the fourth transfer gate transistor TX4.

The third photosensitive region R3 is located within the substrate 11 and next to the second photosensitive region R2, the fourth photosensitive region R4 is located within the substrate 11 and next to the third photosensitive region R3. The floating diffusion region FD is shared between the first photosensitive region R1, the second photosensitive region R2, the third photosensitive region R3 and the fourth photosensitive region R4. For example, as shown in FIG. 1, the first photosensitive region R1 and the second photosensitive region R2 are arranged along the first direction D1, the first photosensitive region R1 and the fourth photosensitive region R4 are arranged along the second direction D2, and the floating diffusion region FD is located at the center of the first photosensitive region R1, the second photosensitive region R2, the third photosensitive region R3 and the fourth photosensitive region R4.

The second photosensitive region R2 and the third photosensitive region R3 are same in doping depth (i.e., a doping depth DD3 of the third photosensitive region R3 is equal to the doping depth DD2 of the second photosensitive region R2) and conductivity type. The first photosensitive region R1 and the fourth photosensitive region R4 are same in doping depth (i.e., a doping depth DD4 of the fourth photosensitive region R4 is equal to the doping depth DD1 of the first photosensitive region R1) and conductivity type. In some embodiments, the third photosensitive region R3 may be referred to as a third photodetector or a third photodiode PD3 (see FIG. 4 or FIG. 5), and the fourth photosensitive region R4 may be referred to as a fourth photodetector or a fourth photodiode PD4 (see FIG. 4 or FIG. 5). In some embodiments, the third photodiode (the third photosensitive region R3) can be disabled by not doping the third photosensitive region R3 with the first conductivity type dopant when performing ion implantation on the first photosensitive region R1/fourth photosensitive region R4, or by doping the third photosensitive region R3 with higher concentration of P-type dopants through an additional ion implantation process, or by doping depth reduction (as shown in FIG. 3). In this way, portions of the grid structure 12 used to shield the third photodiode (the third photosensitive region R3) can be removed, and all the photosensitive regions (including the first photosensitive region R1, the second photosensitive region R2, the third photosensitive region R3 and the fourth photosensitive region R4) in the PDAF pixel 10b of can be exposed by the opening A of the grid structure 12 (i.e., the third photosensitive region R3 and the fourth photosensitive region R4 are also overlapped with the opening A of the grid structure 12). As such, the area of the grid structure 12 can be reduced, and hence the crosstalk issue can be improved.

In the image sensor 1, each of the plurality of image sensing pixels 10a may also include a plurality of (e.g., 2, 4 or more) photosensitive regions R, a plurality of transfer gate transistors TX and one floating diffusion region FD. The plurality of photosensitive regions R are located within the substrate 11, wherein a doping depth DDR of each of the plurality of photosensitive regions R may be the same as the doping depth DD1 of the first photosensitive region R1, and a conductivity type of the plurality of photosensitive regions R may be the same as that of the first photosensitive region R1. In some embodiments, the plurality of photosensitive regions R may be referred to as photodetectors or a photodiodes. The plurality of photosensitive regions R may be separated and electrically isolated from each other through the isolation structure 13, and the isolation structure 13 is disposed laterally between the plurality of photosensitive regions R.

The plurality of transfer gate transistors TX are disposed on the frontside surface SF11 of the substrate 11 and overlapped with the plurality of photosensitive regions R. The floating diffusion region FD is located within the substrate 11 and shared between the plurality of photosensitive regions R. In some embodiments, the grid structure 12 includes a plurality of openings A, and the plurality of photosensitive regions R in each image sensing pixel 10a are overlapped with or exposed by a corresponding opening A.

In some embodiments, the image sensor 1 further includes a plurality of color filters 15. The plurality of color filters 15 are disposed over the backside surface SB11 of the substrate 11. For example, the plurality of color filters 15 are disposed in the plurality of openings A of the grid structure 12. In some embodiments, the opening A of the grid structure 12 corresponding to each of the plurality of PDAF pixels 10b is not disposed with any color filter. In some alternative embodiments, the opening A of the grid structure 12 corresponding to each of the plurality of PDAF pixels 10b is disposed with a corresponding color filter 15. The plurality of color filters 15 may include a plurality of red color filters, a plurality of green color filters and a plurality of blue color filters, but not limited thereto.

In some embodiments, the image sensor 1 further includes a plurality of micro-lenses 16. The plurality of micro-lenses 16 may be disposed over the backside surface SB11 of the substrate 11 and over the plurality of color filters 15. In some embodiments, the micro-lenses 16 have a substantially flat bottom surface abutting the plurality of color filters 15 (or the isolation structure 13) and a curved upper surface. In certain embodiments, the curved upper surface is configured to focus an incident radiation or incident light. During operation of the image sensor 1, the incident radiation or incident light is focused by the micro-lens 16 to the underlying photosensitive regions, where an electron-hole pair may be generated to produce a photocurrent.

In some embodiments, the center of the micro-lens 16 and/or the center of the color filter 15 may be shift with respect to the center of the underlying photosensitive regions to reduce the channel separation (i.e., the sensitivity difference between the subpixels/photodiodes under the same micro-lens) of QPD (Quad Photo Diode) or DPD (Dual Photo Diode).

FIG. 4 and FIG. 5 are two kinds of equivalent circuit diagrams of a PDAF pixel 10b. Referring to FIG. 4 or FIG. 5, the PDAF pixel 10b may further include a lateral overflow transistor LFG, a lateral overflow integration capacitor C, a first reset transistor RST1 and a second reset transistor RST2, but not limited thereto. For example, the PDAF pixel 10b may further include a source follower transistor SF and a selection transistor (or row select transistor) SEL.

The lateral overflow transistor LFG is electrically connected between the floating diffusion region FD and a node N between the lateral overflow transistor LFG, the first reset transistor RST1 and the lateral overflow integration capacitor RST2. The lateral overflow integration capacitor C is electrically connected between the node N and the second reset transistor RST2. The first reset transistor RST1 is electrically connected between the node N and one of a DC voltage supply terminal VDD (see FIG. 4) and a ground voltage terminal VG (see FIG. 5). The second reset transistor RST2 is electrically connected between the lateral overflow integration capacitor C and one of the DC voltage supply terminal VDD (see FIG. 4) and the ground voltage terminal VG (see FIG. 5). The source follower transistor SF is connected between the DC voltage supply terminal VDD and the selection transistor SEL. The selection transistor SEL is connected between the source follower transistor SF and an output Vout.

During operation of the image sensor, the transfer gate transistors (e.g., TX1, TX2, TX3 and TX4) controls charge transfer from the photosensitive regions/photodiodes (e.g., PD1, PD2, PD3 and PD4) to the floating diffusion region FD. If the charge level is sufficiently high within the floating diffusion region FD, the source follower transistor SF is activated and a voltage proportional to the charge at the floating diffusion region FD is output by the selection transistor SEL. In some embodiments, the source follower transistor SF is able to provide high impedance output. For example, the source follower transistor SF may be an amplifier transistor which amplifies the signal of the floating diffusion region FD for readout operation. The lateral overflow transistor LFG is a transistor used to switch the floating diffusion so that charges can be transfer to the lateral overflow integration capacitor C or the first reset transistor RST1. The first reset transistor RST1 may selectively clear charges at the floating diffusion region FD. The second reset transistor RST2 may selectively clear charges at the lateral overflow integration capacitor C.

In the exemplary embodiment, the circuit diagram of an image sensor illustrated in FIG. 4 or FIG. 5 may be a driving circuit for performing a readout function. However, the circuit diagram of the image sensor shown in FIG. 4 or FIG. 5 is merely an example, and the disclosure is not limited thereto. In some alternative embodiments, the image sensor may have different circuit designs.

Referring to FIG. 6 to FIG. 8, an image sensor 1A according to some embodiments of the present disclosure is provided. The image sensor 1A also includes a plurality of image sensing pixels 10a and a plurality of PDAF pixels 10b. However, the pixel design of at least one of the plurality of PDAF pixels 10b in the image sensor 1A is different from that of the PDAF pixel 10b in the image sensor 1 shown in FIG. 1 to FIG. 5.

Specifically, in the PDAF pixel 10b in the image sensor 1A, all the photosensitive regions (including the first photosensitive region R1, the second photosensitive region R2, the third photosensitive region R3 and the fourth photosensitive region R4) are same in doping depth and conductivity type, and the second photodiode PD2 and the third photodiode PD3 are disabled through pixel device design. As shown in the figures, the PDAF pixel 10b in the image sensor 1A includes a first floating diffusion region FD1 and a second floating diffusion region FD2. The first floating diffusion region FD1 is shared between the first photosensitive region R1 and the fourth photosensitive region R4 and electrically connected to the first transfer gate transistor TX1 and the fourth transfer gate transistor TX4. The second floating diffusion region FD2 is shared between the second photosensitive region R2 and the third photosensitive region R4 and electrically connected to the second transfer gate transistor TX2 and the third transfer gate transistor TX3. The lateral overflow transistor LFG is electrically connected between the first floating diffusion region FD1 and the node N between the lateral overflow transistor LFG, the first reset transistor RST1 and the lateral overflow integration capacitor C. The second floating diffusion region FD2 is electrically connected to the DC voltage supply terminal VDD. As such, the electrons generated in the second photodiode PD2 or the third photodiode PD3 through light irradiation can be transferred to the DC voltage supply terminal VDD instead of the lateral overflow integration capacitor C. In some alternative embodiments, although not shown, the first reset transistor RST1 and the second reset transistor RST2 may be electrically connected to the ground voltage terminal VG (see FIG. 5) instead of the DC voltage supply terminal VDD.

By disable the second photodiode PD2 and the third photodiode PD3 through pixel device design, portions of the grid structure 12 used to shield the second photodiode PD2 and the third photodiode PD3 can be removed and all the photosensitive regions (including the first photosensitive region R1, the second photosensitive region R2, the third photosensitive region R3 and the fourth photosensitive region R4) can be exposed by the opening A of the grid structure 12. In this way, the area of the grid structure 12 can be reduced, and hence the crosstalk issue can be improved.

Referring to FIG. 9 to FIG. 11, an image sensor 1B according to some embodiments of the present disclosure is provided. The image sensor 1B also includes a plurality of image sensing pixels 10a and a plurality of PDAF pixels 10b. However, the pixel design of at least one of the plurality of PDAF pixels 10b in the image sensor 1B is different from that of the PDAF pixel 10b in the image sensor 1A shown in FIG. 6 to FIG. 8.

Specifically, the PDAF pixel 10b in the image sensor 1B includes a pair of second transfer gate transistors TX2 overlapped with the second photosensitive region R2 and a pair of third transfer gate transistors TX3 overlapped with the third photosensitive region R3. The first floating diffusion region FD1 is shared between the first floating diffusion region FD1, the second floating diffusion region FD2, the third photosensitive region R3 and the fourth photosensitive region R4. In addition, the first floating diffusion region FD1 is electrically connected to the first transfer gate transistor TX1, one of the pair of second transfer gate transistors TX2, one of the pair of third transfer gate transistors TX3 and the fourth transfer gate transistor TX4. The second floating diffusion region FD2 is electrically connected to the other one of the pair of second transfer gate transistors TX2 and the DC voltage supply terminal VDD. The PDAF pixel 10b in the image sensor 1B further includes a third floating diffusion region FD3 located within the substrate 11 and electrically connected to the other one of the pair of third transfer gate transistors TX3 and the DC voltage supply terminal VDD. As such, the electrons generated in the second photodiode PD2 or the third photodiode PD3 through light irradiation can be transferred to the DC voltage supply terminal VDD instead of the lateral overflow integration capacitor C by turning off the second transfer gate transistor TX2 electrically connected to the first floating diffusion region FD1 and the third transfer gate transistor TX3 electrically connected to the first floating diffusion region FD1. In some alternative embodiments, although not shown, the first reset transistor RST1 and the second reset transistor RST2 may be electrically connected to the ground voltage terminal VG (see FIG. 5) instead of the DC voltage supply terminal VDD.

By disable the second photodiode PD2 and the third photodiode PD3 through pixel device design, portions of the grid structure 12 used to shield the second photodiode PD2 and the third photodiode PD3 can be removed and all the photosensitive regions (including the first photosensitive region R1, the second photosensitive region R2, the third photosensitive region R3 and the fourth photosensitive region R4) can be exposed by the opening A of the grid structure 12. In this way, the area of the grid structure 12 can be reduced, and hence the crosstalk issue can be improved.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, an image sensor includes a plurality of pixels. At least one pixel among the plurality of pixels includes a first photosensitive region, a second photosensitive region, a first transfer gate transistor, a second transfer gate transistor and a floating diffusion region. The first photosensitive region is located within a substrate. The second photosensitive region is located within the substrate and next to the first photosensitive region. The first photosensitive region and the second photosensitive region are different in at least one of doping depth and conductivity type, and the first photosensitive region and the second photosensitive region are overlapped with an opening of a grid structure disposed on a backside surface of the substrate. The first transfer gate transistor is disposed on a frontside surface of the substrate and overlapped with the first photosensitive region. The second transfer gate transistor is disposed on the frontside surface of the substrate and overlapped with the second photosensitive region. The floating diffusion region is located within the substrate and shared between the first photosensitive region and the second photosensitive region. In some embodiments, the first photosensitive region has a first conductivity type, the second photosensitive region and the substrate have a second conductivity type different from the first conductivity type, and an impurity concentration of the second photosensitive region is equal to or higher than that of the substrate. In some embodiments, the second conductivity type is P-type, and the impurity concentration of the second photosensitive region is equal to or higher than 10²⁰/cm³. In some embodiments, the first photosensitive region and the second photosensitive region have a first conductivity type, the substrate has a second conductivity type different from the first conductivity type, and the doping depth of the second photosensitive region is smaller than that of the first photosensitive region. In some embodiments, a distance between the second photosensitive region and the floating diffusion region is larger than a distance between the first photosensitive region and the floating diffusion region. In some embodiments, the at least one pixel among the plurality of pixels further includes a third photosensitive region, a fourth photosensitive region, a third transfer gate transistor and a fourth transfer gate transistor. The third photosensitive region is located within the substrate and next to the second photosensitive region. The fourth photosensitive region is located within the substrate and next to the third photosensitive region. The third transfer gate transistor is disposed on the frontside surface of the substrate and overlapped with the third photosensitive region. The fourth transfer gate transistor is disposed on the frontside surface of the substrate and overlapped with the fourth photosensitive region. The floating diffusion region is shared between the first photosensitive region, the second photosensitive region, the third photosensitive region and the fourth photosensitive region. The third photosensitive region and the fourth photosensitive region are also overlapped with the opening of the grid structure. The second photosensitive region and the third photosensitive region are same in doping depth and conductivity type. The first photosensitive region and the fourth photosensitive region are same in doping depth and conductivity type. In some embodiments, the first photosensitive region and the second photosensitive region are arranged along a first direction, and the first photosensitive region and the fourth photosensitive region are arranged along a second direction perpendicular to the first direction. In some embodiments, the at least one pixel among the plurality of pixels is configured for phase detection autofocus. In some embodiments, the at least one pixel among the plurality of pixels further includes a lateral overflow transistor, a lateral overflow integration capacitor, a first reset transistor and a second reset transistor. The lateral overflow transistor is electrically connected between the floating diffusion region and a node between the lateral overflow transistor, the first reset transistor and the lateral overflow integration capacitor. The lateral overflow integration capacitor is electrically connected between the node and the second reset transistor. The first reset transistor is electrically connected between the node and one of a DC voltage supply terminal and a ground voltage terminal. The second reset transistor is electrically connected between the lateral overflow integration capacitor and one of the DC voltage supply terminal and the ground voltage terminal. In some embodiments, the image sensor further includes an isolation structure disposed from the backside surface to a point between the backside surface and the frontside surface, and the isolation structure is disposed laterally between the first photosensitive region and the second photosensitive region.

According to some embodiments, an image sensor includes a plurality of pixels. At least one pixel among the plurality of pixels includes a first photosensitive region, a second photosensitive region, a first transfer gate transistor, a second transfer gate transistor, a first floating diffusion region and a second floating diffusion region. The first photosensitive region is located within a substrate. The second photosensitive region is located within the substrate and next to the first photosensitive region. The first photosensitive region and the second photosensitive region are overlapped with an opening of a grid structure disposed on a backside surface of the substrate. The first transfer gate transistor is disposed on a frontside surface of the substrate and overlapped with the first photosensitive region. The second transfer gate transistor is disposed on the frontside surface of the substrate and overlapped with the second photosensitive region. The first floating diffusion region is located within the substrate and electrically connected to the first transfer gate transistor. The second floating diffusion region is located within the substrate and electrically connected to the second transfer gate transistor. In some embodiments, the at least one pixel among the plurality of pixels further includes a third photosensitive region, a fourth photosensitive region, a third transfer gate transistor and a fourth transfer gate transistor. The third photosensitive region is located within the substrate and next to the second photosensitive region. The fourth photosensitive region is located within the substrate and next to the third photosensitive region. The third transfer gate transistor is disposed on the frontside surface of the substrate and overlapped with the third photosensitive region. The fourth transfer gate transistor is disposed on the frontside surface of the substrate and overlapped with the fourth photosensitive region. The first floating diffusion region is shared between the first photosensitive region and the fourth photosensitive region. The second floating diffusion region is shared between the second photosensitive region and the third photosensitive region. The third photosensitive region and the fourth photosensitive region are also overlapped with the opening of the grid structure. In some embodiments, the at least one pixel among the plurality of pixels is configured for phase detection autofocus. In some embodiments, the at least one pixel among the plurality of pixels further includes a lateral overflow transistor, a lateral overflow integration capacitor, a first reset transistor and a second reset transistor. The lateral overflow transistor is electrically connected between the first floating diffusion region and a node between the lateral overflow transistor, the first reset transistor and the lateral overflow integration capacitor. The lateral overflow integration capacitor is electrically connected between the node and the second reset transistor. The first reset transistor is electrically connected between the node and one of a DC voltage supply terminal and a ground voltage terminal. The second reset transistor is electrically connected between the lateral overflow integration capacitor and one of the DC voltage supply terminal and the ground voltage terminal. The second floating diffusion region is electrically connected to the DC voltage supply terminal. In some embodiments, the image sensor further includes an isolation structure disposed from the backside surface to a point between the backside surface and the frontside surface, and the isolation structure is disposed laterally between the first photosensitive region and the second photosensitive region.

According to some embodiments, an image sensor includes a plurality of pixels. At least one pixel among the plurality of pixels includes a first photosensitive region, a second photosensitive region, a first transfer gate transistor, a pair of second transfer gate transistors, a first floating diffusion region and a second floating diffusion region. The first photosensitive region is located within a substrate. The second photosensitive region is located within the substrate and next to the first photosensitive region. The first photosensitive region and the second photosensitive region are overlapped with an opening of a grid structure disposed on a backside surface of the substrate. The first transfer gate transistor is disposed on a frontside surface of the substrate and overlapped with the first photosensitive region. The pair of second transfer gate transistors are disposed on the frontside surface of the substrate and overlapped with the second photosensitive region. The first floating diffusion region is located within the substrate and electrically connected to the first transfer gate transistor and one second transfer gate transistor among the pair of second transfer gate transistors. The second floating diffusion region is located within the substrate and electrically connected to the other one second transfer gate transistor among the pair of second transfer gate transistors. In some embodiments, the at least one pixel among the plurality of pixels further includes a third photosensitive region, a fourth photosensitive region, a pair of third transfer gate transistors, a fourth transfer gate transistor and a third floating diffusion region. The third photosensitive region is located within the substrate and next to the second photosensitive region. The fourth photosensitive region is located within the substrate and next to the third photosensitive region. The pair of third transfer gate transistors are disposed on the frontside surface of the substrate and overlapped with the third photosensitive region. The fourth transfer gate transistor is disposed on the frontside surface of the substrate and overlapped with the fourth photosensitive region. The third floating diffusion region is located within the substrate and electrically connected to one third transfer gate transistor among the pair of third transfer gate transistors. The first floating diffusion region is further electrically connected to the other one third transfer gate transistor among the pair of third transfer gate transistors and the fourth transfer gate transistor. The third photosensitive region and the fourth photosensitive region are also overlapped with the opening of the grid structure. In some embodiments, the at least one pixel among the plurality of pixels is configured for phase detection autofocus. In some embodiments, the at least one pixel among the plurality of pixels further includes a lateral overflow transistor, a lateral overflow integration capacitor, a first reset transistor and a second reset transistor. The lateral overflow transistor is electrically connected between the first floating diffusion region and a node between the lateral overflow transistor, the first reset transistor and the lateral overflow integration capacitor. The lateral overflow integration capacitor is electrically connected between the node and the second reset transistor. The first reset transistor is electrically connected between the node and one of a DC voltage supply terminal and a ground voltage terminal. The second reset transistor is electrically connected between the lateral overflow integration capacitor and one of the DC voltage supply terminal and the ground voltage terminal. The second floating diffusion region is electrically connected to the DC voltage supply terminal. In some embodiments, the image sensor further includes an isolation structure disposed from the backside surface to a point between the backside surface and the frontside surface, and the isolation structure is disposed laterally between the first photosensitive region and the second photosensitive region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor comprising a plurality of pixels, and at least one pixel among the plurality of pixels comprises:
a first photosensitive region located within a substrate;
a second photosensitive region located within the substrate and next to the first photosensitive region, wherein the first photosensitive region and the second photosensitive region are different in at least one of doping depth and conductivity type, and the first photosensitive region and the second photosensitive region are overlapped with an opening of a grid structure disposed on a backside surface of the substrate;
a first transfer gate transistor disposed on a frontside surface of the substrate and overlapped with the first photosensitive region;
a second transfer gate transistor disposed on the frontside surface of the substrate and overlapped with the second photosensitive region; and
a floating diffusion region located within the substrate and shared between the first photosensitive region and the second photosensitive region.

2. The image sensor as claimed in claim 1, wherein the first photosensitive region has a first conductivity type, the second photosensitive region and the substrate have a second conductivity type different from the first conductivity type, and an impurity concentration of the second photosensitive region is equal to or higher than that of the substrate.

3. The image sensor as claimed in claim 2, wherein the second conductivity type is P-type, and the impurity concentration of the second photosensitive region is equal to or higher than 10²⁰/cm³.

4. The image sensor as claimed in claim 1, wherein the first photosensitive region and the second photosensitive region have a first conductivity type, the substrate has a second conductivity type different from the first conductivity type, and the doping depth of the second photosensitive region is smaller than that of the first photosensitive region.

5. The image sensor as claimed in claim 4, wherein a distance between the second photosensitive region and the floating diffusion region is larger than a distance between the first photosensitive region and the floating diffusion region.

6. The image sensor as claimed in claim 1, wherein the at least one pixel among the plurality of pixels further comprises:
a third photosensitive region located within the substrate and next to the second photosensitive region;
a fourth photosensitive region located within the substrate and next to the third photosensitive region;
a third transfer gate transistor disposed on the frontside surface of the substrate and overlapped with the third photosensitive region; and
a fourth transfer gate transistor disposed on the frontside surface of the substrate and overlapped with the fourth photosensitive region, and wherein:
the floating diffusion region is shared between the first photosensitive region, the second photosensitive region, the third photosensitive region and the fourth photosensitive region,
the third photosensitive region and the fourth photosensitive region are also overlapped with the opening of the grid structure,
the second photosensitive region and the third photosensitive region are same in doping depth and conductivity type, and
the first photosensitive region and the fourth photosensitive region are same in doping depth and conductivity type.

7. The image sensor as claimed in claim 6, wherein the first photosensitive region and the second photosensitive region are arranged along a first direction, and the first photosensitive region and the fourth photosensitive region are arranged along a second direction perpendicular to the first direction.

8. The image sensor as claimed in claim 1, wherein the at least one pixel among the plurality of pixels is configured for phase detection autofocus.

9. The image sensor as claimed in claim 1, wherein the at least one pixel among the plurality of pixels further comprises a lateral overflow transistor, a lateral overflow integration capacitor, a first reset transistor and a second reset transistor, and wherein:
the lateral overflow transistor is electrically connected between the floating diffusion region and a node between the lateral overflow transistor, the first reset transistor and the lateral overflow integration capacitor,
the lateral overflow integration capacitor is electrically connected between the node and the second reset transistor,
the first reset transistor is electrically connected between the node and one of a DC voltage supply terminal and a ground voltage terminal, and
the second reset transistor is electrically connected between the lateral overflow integration capacitor and one of the DC voltage supply terminal and the ground voltage terminal.

10. The image sensor as claimed in claim 1, further comprising:
an isolation structure disposed from the backside surface to a point between the backside surface and the frontside surface, wherein the isolation structure is disposed laterally between the first photosensitive region and the second photosensitive region.

11. An image sensor comprising a plurality of pixels, and at least one pixel among the plurality of pixels comprises:
a first photosensitive region located within a substrate;
a second photosensitive region located within the substrate and next to the first photosensitive region, wherein the first photosensitive region and the second photosensitive region are overlapped with an opening of a grid structure disposed on a backside surface of the substrate;
a first transfer gate transistor disposed on a frontside surface of the substrate and overlapped with the first photosensitive region;
a second transfer gate transistor disposed on the frontside surface of the substrate and overlapped with the second photosensitive region;
a first floating diffusion region located within the substrate and electrically connected to the first transfer gate transistor; and
a second floating diffusion region located within the substrate and electrically connected to the second transfer gate transistor.

12. The image sensor as claimed in claim 11, wherein the at least one pixel among the plurality of pixels further comprises:
a third photosensitive region located within the substrate and next to the second photosensitive region;
a fourth photosensitive region located within the substrate and next to the third photosensitive region;
a third transfer gate transistor disposed on the frontside surface of the substrate and overlapped with the third photosensitive region; and
a fourth transfer gate transistor disposed on the frontside surface of the substrate and overlapped with the fourth photosensitive region, and wherein:
the first floating diffusion region is shared between the first photosensitive region and the fourth photosensitive region,
the second floating diffusion region is shared between the second photosensitive region and the third photosensitive region, and
the third photosensitive region and the fourth photosensitive region are also overlapped with the opening of the grid structure.

13. The image sensor as claimed in claim 12, wherein the at least one pixel among the plurality of pixels is configured for phase detection autofocus.

14. The image sensor as claimed in claim 12, wherein the at least one pixel among the plurality of pixels further comprises a lateral overflow transistor, a lateral overflow integration capacitor, a first reset transistor and a second reset transistor, and wherein:
the lateral overflow transistor is electrically connected between the first floating diffusion region and a node between the lateral overflow transistor, the first reset transistor and the lateral overflow integration capacitor,
the lateral overflow integration capacitor is electrically connected between the node and the second reset transistor,
the first reset transistor is electrically connected between the node and one of a DC voltage supply terminal and a ground voltage terminal,
the second reset transistor is electrically connected between the lateral overflow integration capacitor and one of the DC voltage supply terminal and the ground voltage terminal, and
the second floating diffusion region is electrically connected to the DC voltage supply terminal.

15. The image sensor as claimed in claim 11, further comprising:
an isolation structure disposed from the backside surface to a point between the backside surface and the frontside surface, wherein the isolation structure is disposed laterally between the first photosensitive region and the second photosensitive region.

16. An image sensor comprising a plurality of pixels, and at least one pixel among the plurality of pixels comprises:
a first photosensitive region located within a substrate;
a second photosensitive region located within the substrate and next to the first photosensitive region, wherein the first photosensitive region and the second photosensitive region are overlapped with an opening of a grid structure disposed on a backside surface of the substrate;
a first transfer gate transistor disposed on a frontside surface of the substrate and overlapped with the first photosensitive region;
a pair of second transfer gate transistors disposed on the frontside surface of the substrate and overlapped with the second photosensitive region;
a first floating diffusion region located within the substrate and electrically connected to the first transfer gate transistor and one second transfer gate transistor among the pair of second transfer gate transistors; and
a second floating diffusion region located within the substrate and electrically connected to the other one second transfer gate transistor among the pair of second transfer gate transistors.

17. The image sensor as claimed in claim 16, wherein the at least one pixel among the plurality of pixels further comprises:
a third photosensitive region located within the substrate and next to the second photosensitive region;
a fourth photosensitive region located within the substrate and next to the third photosensitive region;
a pair of third transfer gate transistors disposed on the frontside surface of the substrate and overlapped with the third photosensitive region;
a fourth transfer gate transistor disposed on the frontside surface of the substrate and overlapped with the fourth photosensitive region; and
a third floating diffusion region located within the substrate and electrically connected to one third transfer gate transistor among the pair of third transfer gate transistors, and wherein:
the first floating diffusion region is further electrically connected to the other one third transfer gate transistor among the pair of third transfer gate transistors and the fourth transfer gate transistor, and
the third photosensitive region and the fourth photosensitive region are also overlapped with the opening of the grid structure.

18. The image sensor as claimed in claim 16, wherein the at least one pixel among the plurality of pixels is configured for phase detection autofocus.

19. The image sensor as claimed in claim 16, wherein the at least one pixel among the plurality of pixels further comprises a lateral overflow transistor, a lateral overflow integration capacitor, a first reset transistor and a second reset transistor, and wherein:
the lateral overflow transistor is electrically connected between the first floating diffusion region and a node between the lateral overflow transistor, the first reset transistor and the lateral overflow integration capacitor,
the lateral overflow integration capacitor is electrically connected between the node and the second reset transistor,
the first reset transistor is electrically connected between the node and one of a DC voltage supply terminal and a ground voltage terminal,
the second reset transistor is electrically connected between the lateral overflow integration capacitor and one of the DC voltage supply terminal and the ground voltage terminal, and
the second floating diffusion region is electrically connected to the DC voltage supply terminal.

20. The image sensor as claimed in claim 16, further comprising:
an isolation structure disposed from the backside surface to a point between the backside surface and the frontside surface, wherein the isolation structure is disposed laterally between the first photosensitive region and the second photosensitive region.
